(19) United States
(12) Patent Application Publication
(10) Pub. No.: US 2026/0304656 A1
(43) Pub. Date: Oct. 1, 2026

(54) DISPLAY PANEL AND ELECTRONIC DEVICE

(71) Applicants: Chengdu BOE Optoelectronics Technology Co., Ltd., Chengdu, Sichuan (CN); BOE Technology Group Co., Ltd., Beijing (CN)

(72) Inventors: Zheng BAO, Beijing (CN); Gong CHEN, Beijing (CN); Yuan FANG, Beijing (CN); Mingqiang WANG, Beijing (CN); Xueying HE, Beijing (CN); Yi ZHANG, Beijing (CN); Lian XIANG, Beijing (CN); Peng YANG, Beijing (CN); Danyang BI, Beijing (CN); Jiaxiang ZHANG, Beijing (CN)

(21) Appl. No.: 19/478,048

(22) PCT Filed: May 30, 2024
(86) PCT No.: PCT/CN2024/096430

§ 371 Date: Oct. 23, 2025

(30) Foreign Application Priority Data
Jun. 30, 2023 (CN) 202310801954.1

(51) Int. Cl. H05K 5/02; H05K 1/11

(52) U.S. Cl. CPC H05K 5/0247; H05K 1/117; H05K 2201/09027; H05K 2201/10128

(57) ABSTRACT

Provided is display panel, including a display substrate having a display region and a bonding region, wherein the bonding region is provided with multiple pins including a first pin; a driving chip disposed on the bonding region, wherein the driving chip is provided with multiple interfaces including an enable interface, and the enable interface is connected to the first pin; and a circuit board, wherein the circuit board is provided with multiple gold fingers including a first gold finger, and the first gold finger is connected to the first pin, wherein in response to a first potential signal being applied to the enable interface through the circuit board, the communication protocol is not used; and in response to a second potential signal being applied to the enable interface through the circuit board, the communication protocol is used.

The present disclosure is a U.S. national stage of international application No. PCT/CN2024/096430, which claims priority to Chinese Patent Application No. 202310801954.1, filed on Jun. 30, 2023, and entitled “DISPLAY PANEL AND ELECTRONIC DEVICE”, the disclosure of which is herein incorporated by reference in its entirety.

### TECHNICAL FIELD

The present disclosure relates to a display panel and an electronic device.

### BACKGROUND

Wearable devices typically include a display panel. The display panel includes a display substrate, as well as a driving chip and a flexible circuit board that are bonded to the display substrate. The MIPI protocol is typically used for signal transmission between the driving chip and the flexible circuit board as well as the display substrate, and the MIPI protocol can transmit high-speed signals with large data volumes, low power consumption, and excellent anti-interference performance. However, in the always-on display (AOD) mode in which high-speed signal transmission is not required and the data volume is also small, continuing to use the MIPI protocol will not be conducive to reducing the system load and power consumption.

### SUMMARY

According to some embodiments of the present disclosure, a display panel is provided. The display panel includes: a display substrate having a display region and a bonding region, wherein the display region includes multiple pixel units and the bonding region is provided with multiple pins including a first pin; a driving chip disposed on the bonding region, wherein the driving chip is provided with multiple interfaces including an enable interface, wherein the enable interface is configured to enable a communication protocol and the enable interface is connected to the first pin; and a circuit board, wherein the circuit board is provided with multiple gold fingers including a first gold finger, the multiple gold fingers are connected to the multiple pins, and the first gold finger is connected to the first pin, wherein in response to a first potential signal being applied to the enable interface through the circuit board, the communication protocol is not used; and in response to a second potential signal being applied to the enable interface through the circuit board, the communication protocol is used.

In some embodiments, the communication protocol includes a queue serial peripheral interface (QSPI) protocol.

In some embodiments, a mobile industry processor interface (MIPI) communication protocol is used in response to the QSPI protocol not being used.

In some embodiments, the multiple gold fingers of the circuit board are connected to the multiple pins in a bonding manner, and the first gold finger is connected to the first pin in the bonding manner.

In some embodiments, the first potential signal is a high-potential signal, and the second potential signal is a low-potential signal.

In some embodiments, the multiple interfaces further include a second interface and a third interface, wherein one of the second interface and the third interface is configured to provide the first potential signal, and the other thereof is configured to provide the second potential signal; the multiple pins further include a second pin and a third pin, wherein the second interface is connected to the second pin, and the third interface is connected to the third pin; the multiple gold fingers further include a second gold finger and a third gold finger, wherein the second gold finger is connected to the second pin, and the third gold finger is connected to the third pin; the circuit board further includes multiple pads, wherein the multiple pads include a first pad, a second pad, and a third pad, wherein the first pad is connected to the first gold finger, the second pad is connected to the second gold finger, and the third pad is connected to the third gold finger; and the first pad is selectively connected to either the second pad or the third pad.

In some embodiments, the second gold finger is connected to the second pin in a bonding manner, and the third gold finger is connected to the third pin in a bonding manner.

In some embodiments, the first pad is connected to the first gold finger through a trace inside the circuit board, the second pad is connected to the second gold finger through a trace inside the circuit board, and the third pad is connected to the third gold finger through a trace inside the circuit board.

In some embodiments, the second pad and the third pad are both adjacent to the first pad, and the second pad and the third pad are disposed on different sides of the first pad.

In some embodiments, the first pad is connected to the second pad through a conductor disposed on a surface of the circuit board; or the first pad is connected to the third pad through a conductor disposed on a surface of the circuit board.

In some embodiments, the circuit board further includes a fifth pad and a board-to-board interface, wherein the fifth pad has a first potential and configured to provide the first potential signal to the first gold finger, and a resistor element is connected between the fifth pad and the first gold finger; and the board-to-board interface is connected to the first gold finger and is switchable between a first state and a second state; and when the board-to-board interface is in the first state, the board-to-board interface is in a high-impedance state or a floating state, and when the board-to-board interface is in the second state, the board-to-board interface has a second potential and configured to provide the second potential signal to the enable interface.

In some embodiments, the fifth pad is grounded.

In some embodiments, the multiple interfaces further include a second interface configured to selectively provide the first potential signal or the second potential signal; the multiple pins further include a second pin connected to the second interface; and the multiple gold fingers further include a second gold finger connected to the second pin, the second gold finger being connected to the first gold finger.

In some embodiments, the second interface is a general-purpose input/output (GPIO) interface, and the second interface is programmable to output the first potential signal or the second potential signal.

According to some embodiments of the present disclosure, an electronic device is provided. The electronic device includes the display panel as described above.

It should be understood that the above general description and the following detailed description are merely exemplary and illustrative and do not limit the present disclosure.

### BRIEF DESCRIPTION OF DRAWINGS

The accompanying drawings, which are incorporated herein and constitute a part of this specification, illustrate embodiments consistent with the present disclosure and, together with the description, serve to explain the principles of the present disclosure.

FIG. 1 is a structural schematic diagram of a display panel applicable to a wearable device;

FIG. 2 is a schematic diagram of a circuit connection of a partial structure of the display panel shown in FIG. 1;

FIG. 3 is a structural schematic diagram of a display panel according to some embodiments of the present disclosure;

FIG. 4 is a schematic diagram of an operating state of the display panel shown in FIG. 3;

FIG. 5 is a schematic diagram of another operating state of the display panel shown in FIG. 3;

FIG. 6 is a structural schematic diagram of another display panel according to some embodiments of the present disclosure;

FIG. 7 is a schematic diagram of an operating state of the display panel shown in FIG. 6;

FIG. 8 is a schematic diagram of another operating state of the display panel shown in FIG. 6;

FIG. 9 is a structural schematic diagram of yet another display panel according to some embodiments of the present disclosure;

FIG. 10 is a structural schematic diagram of still yet another display panel according to some embodiments of the present disclosure; and

FIGS. 11 to 18 are schematic diagrams of a method for manufacturing a circuit board according to some embodiments of the present disclosure.

### DETAILED DESCRIPTION

Exemplary embodiments will be described in detail herein, with examples illustrated in the accompanying drawings. When the following description refers to the drawings, the same numerals in different drawings represent the same or similar elements, unless otherwise indicated. The embodiments described in the following exemplary embodiments do not represent all embodiments consistent with the present disclosure. Rather, they are merely examples of devices and methods consistent with certain aspects of the present disclosure, as detailed in the appended claims.

The terms used in the present disclosure are for the purpose of describing specific embodiments only and are not intended to limit the present disclosure. Unless otherwise defined, technical or scientific terms used in the present disclosure should have the normal meaning understood by those of general skill in the art. The term “one” or “a/an” and similar terms used in the specification and claims of the present disclosure denote at least one, instead of limiting the quantity. The expression “a plurality of” or “multiple” refers to two or more. The word “comprise” or “include” and similar terms mean that the element or object appearing before the word “comprise” or “include” covers the listed elements, objects, and equivalents thereof appearing after the word “comprise” or “include”, without excluding other elements or objects. The term “connection” or “connected” and similar terms are not limited to physical or mechanical connections, and may include electrical connections, and the connection may be direct or indirect. The words “upper” and/or “lower” and similar words are used for ease of description only and are not limited to a position or a spatial orientation. As used in this specification and the appended claims of the present disclosure, the singular forms “a,” “said,” and “the” are intended to include plural forms as well, unless the context clearly indicates otherwise. It should also be understood that the term “and/or” used herein means that any or all of the possible combinations of one or more items listed in an associated manner.

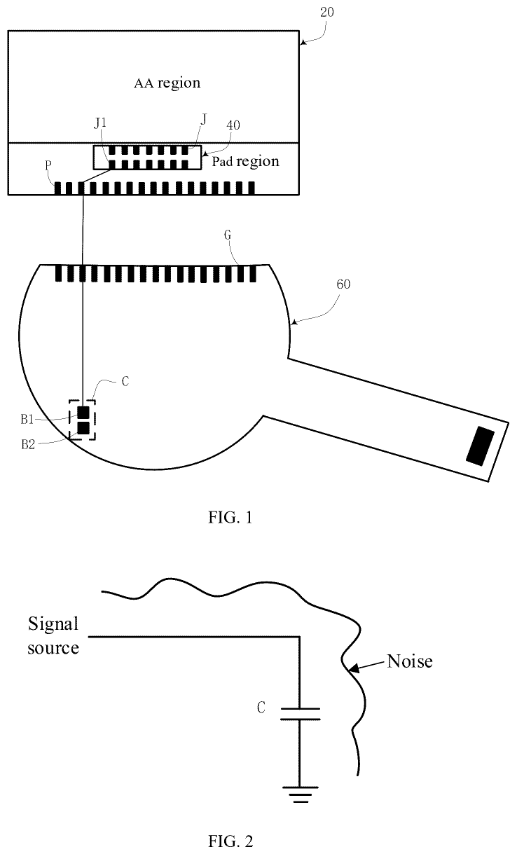

FIG. 1 is a structural schematic diagram of a display panel applicable to a wearable device. The display panel is a flexible OLED display panel. In order to reduce the size and boundary of the entire display panel, a chip-on-panel (COP) technology is usually used to directly bond a driving chip 40 to a display substrate 20, and multiple interfaces J on the driving chip 40 are connected to a plurality of pins P on the display substrate 20. During assembly of a circuit board 60, multiple gold fingers G on the circuit board 60 are directly bound to the multiple pins P on the display substrate 20.

Referring to both FIGS. 1 and 2, signals from some power interfaces J1 on the driving chip 40 need to be routed to the circuit board 60 for connection to an external capacitor C. One terminal (or one electrode plate) B1 of the capacitor C is connected to the power interface J1 of the driving chip 40, and the other terminal (or another electrode plate) B2 thereof is grounded. The external capacitor C has a filtering function. In response to a power supply signal output by the driving chip 40 being mixed with a noise signal, the capacitor C will filter out the noise signal and channel it to ground. Certainly, in some cases, components such as a transient voltage suppressor (TVS), a diode, a flash memory, an ambient light sensor (ALS), a ZIF connector, and a ferrite bead may also be included. Corresponding pads are reserved on the circuit board 60, and these components are mounted on the surface of the circuit board 60 using surface mount technology (SMT).

The wearable device often uses the mobile industry processor interface (MIPI) protocol for signal transmission. This protocol allows for high-speed signal transmission with large data volumes, low power consumption, and excellent anti-interference performance. However, in an always-on display (AOD) mode, high-speed signal transmission is not required, and the data volume is also small. Consequently, at this time, a more optimal approach is to introduce the queue serial peripheral interface (QSPI) communication protocol, allowing for transmitting data using the QSPI in the AOD mode. Nevertheless, the technology for applying the QSPI protocol to the AOD mode is not yet mature, so the present disclosure provides a solution that is compatible with both scenarios: using the QSPI protocol and operating without it.

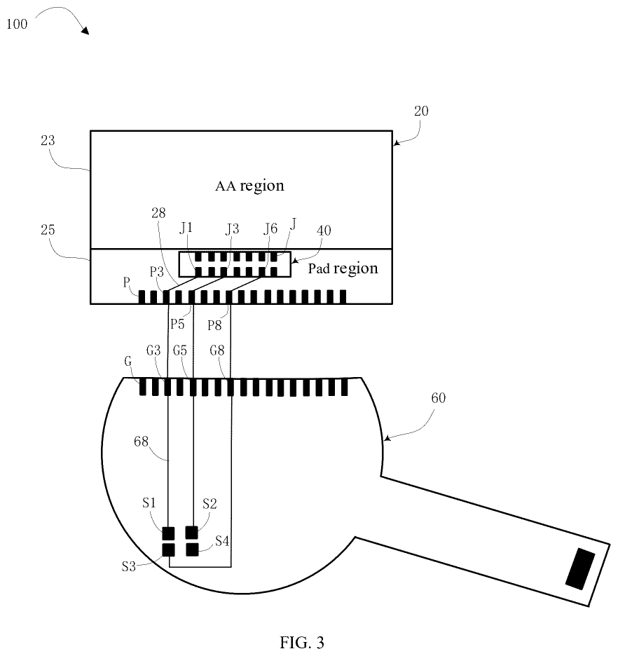

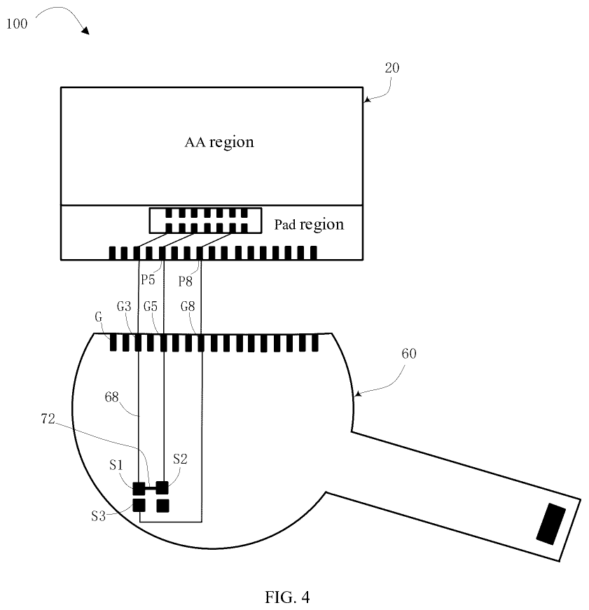

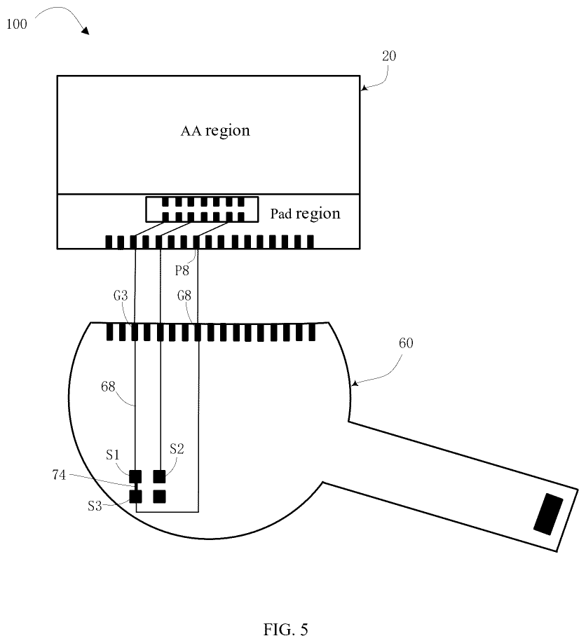

FIG. 3 is a structural schematic diagram of a display panel 100 according to some embodiments of the present disclosure. FIG. 4 is a schematic diagram of an operating state of the display panel 100 shown in FIG. 3. FIG. 5 is a schematic diagram of another operating state of the display panel 100 shown in FIG. 3.

Referring to FIG. 3, the display panel 100 includes a display substrate 20, a driving chip 40, and a circuit board 60. The display substrate 20 includes a display region 23 (AA region) and a bonding region 25 (pad region). The bonding region 25 is provided with multiple pins P, and the multiple pins P include a first pin P3.

The driving chip 40 is disposed in the bonding region 25 of the display substrate 20 and includes multiple interfaces J. The multiple interfaces J include an enable interface J1 (i.e., an EN interface or an EN PIN). The enable interface J1 is configured to control the use of a specific communication protocol, and the enable interface J1 is electrically connected to the first pin P3.

The circuit board 60 includes multiple gold fingers G, the multiple gold fingers G include a first gold finger G3, the multiple gold fingers G of the circuit board 60 are connected to the multiple pins P, and the first gold finger G3 is connected to the first pin P3.

Through the circuit board 60, a first potential signal or a second potential signal is applicable to the enable interface J1. In response to the first potential signal being applied to the enable interface J1, the specific communication protocol is not used; and in response to the second potential signal being applied to the enable interface, the specific communication protocol is used.

In the above embodiments, the specific communication protocol is either selected for use or not. This is conducive to exerting the advantages of the communication protocol and avoiding its disadvantages. For example, when it is detected that the moment is suitable for using the communication protocol, the second potential signal is applied to the enable interface, so that the specific communication protocol is used. When it is detected that the moment is not suitable for using the communication protocol, the first potential signal is applied to the enable interface, so that the specific communication protocol is not used.

There are various positional relationships between the display region 23 and the bonding region 25. In some embodiments, the display region 23 is a main portion of the display substrate 20, which includes multiple pixel units for displaying images; and the bonding region 25 is disposed on one edge of the display substrate 20 to enable electrical connection to external components. In some embodiments, the display region 23 is adjacent to the bonding region 25.

There are various arrangement modes for the multiple pins P. In some embodiments, the multiple pins P are disposed on a side of the bonding region 25 distal from the display region 23 and arranged along a straight line. In other embodiments, the multiple pins P are arranged along multiple sides of the bonding region 25. For example, the multiple pins P are arranged along three outer sides of the bonding region 25 (excluding a side of the bonding region 25 adjacent to the display region 23).

There are various mounting methods for the driving chip 40. In some embodiments, the driving chip 40 is mounted in the bonding region 25 in a bonding manner. In some embodiments, the driving chip 40 is mounted in the bonding region 25 by plug-in connection. For example, the driving chip 40 is provided with a connector, and the bonding region 25 is provided with a matching connector. By plugging the connector into the matching connector, the driving chip 40 is mounted in the bonding region 25.

The enable interface J1 is electrically connected to the first pin P3 through a trace 28 in the bonding region 25. In some embodiments, the trace 28 is disposed inside the bonding region 25 of the display substrate 20. In some embodiments, the trace 28 is disposed on a surface of the bonding region 25 of the display substrate 20. For example, after the driving chip 40 is mounted in the bonding region 25, a discrete conductive wire is provided with one end being soldered to the enable interface J1 and the other end being soldered to the first pin P3. The conductive wire serves as the trace 28.

The communication protocol may be any communication protocol. In some embodiments, the communication protocol is the QSPI protocol. The QSPI protocol, i.e., the queue serial peripheral interface communication protocol, is set such that in a case where the display panel is in the AOD mode, the QSPI protocol is used. Because in the AOD mode, the display panel does not need to transmit high-speed signals and handles very little data, and the use of the QSPI communication protocol is optimal, which helps reduce the workload of the driving chip. It may further be set such that in a case where the display panel is in other modes (for example, a normal display mode), the QSPI protocol is not used and other protocols are used. The other protocols include the MIPI protocol. The MIPI protocol transmits high-speed signals with a large data volume, low power consumption, and excellent anti-interference performance.

In some embodiments, the multiple gold fingers G of the circuit board 60 are connected to the multiple pins P by bonding, and the first gold finger G3 is connected to the first pin P3 by bonding.

The multiple gold fingers G are arranged in various ways. In some embodiments, the multiple gold fingers G are disposed on a side of the circuit board 60 adjacent to the bonding region 25 and arranged along a straight line.

In some embodiments, the circuit board 60 is a flexible printed circuit (FPC) board.

In some embodiments, the first potential signal is a high-potential signal, and the second potential signal is a low-potential signal. That is, in response to the high-potential signal being applied to the enable interface J1, the specific communication protocol is not used; and in response to the low-potential signal being applied to the enable interface J1, the specific communication protocol is used.

Further, the multiple interfaces J further include a second interface J3 and a third interface J6. The second interface J3 is configured to provide a first potential signal, and the third interface J6 is configured to provide a second potential signal. The multiple pins P further include a second pin P5 and a third pin P8. The second interface J3 is electrically connected to the second pin P5, and the third interface J6 is electrically connected to the third pin P8.

The multiple gold fingers G further include a second gold finger G5 and a third gold finger G8, the second gold finger G5 is connected to the second pin P5, and the third gold finger G8 is connected to the third pin P8.

The circuit board 60 further includes multiple pads, the multiple pads include a first pad S1, a second pad S2 and a third pad S3, the first pad S1 is electrically connected to the first gold finger G3, the second pad S2 is electrically connected to the second gold finger G5, and the third pad S3 is electrically connected to the third gold finger G8.

Due to the above connection, the first pad S1 is electrically connected to the enable interface J1; the second pad S2 is electrically connected to the second interface J3 and has a first potential; and the third pad S3 is electrically connected to the third interface J6 and has a second potential.

In a case where the specific communication protocol is not required to be used, the first pad S1 and the second pad S2 are connected, as shown in FIG. 4, such that the enable interface J1 is connected to the first potential signal; and at this time, the third interface J6 and the third pad S3 that have the second potential are in a floating state.

In a case where the specific communication protocol is required to be used, the first pad S1 is connected to the third pad S3, as shown in FIG. 5, such that the enable interface J1 is connected to the second potential signal; and at this time, the second interface J3 and the second pad S2 that have the first potential are in a floating state.

Referring to FIGS. 3 to 5, the second interface J3 is electrically connected to the second pin P5 through a trace 28 in the bonding region 25; and the third interface J6 is electrically connected to the third pin P8 through a trace 28 in the bonding region 25. In some embodiments, the trace 28 for connecting the second interface J3 and the second pin P5 and/or the trace 28 for connecting the third interface J6 and the third pin P8 are/is disposed inside the bonding region 25 of the display substrate 20. In some embodiments, the trace 28 for connecting the second interface J3 and the second pin P5 and/or the trace 28 for connecting the third interface J6 and the third pin P8 are disposed on a surface of the bonding region 25 of the display substrate 20. For example, after the driving chip 40 is mounted in the bonding region 25, two discrete conductive wires are provided, wherein one end of a first conductive wire is soldered to the second interface J3 and the other end thereof is soldered to the second pin P5; and one end of a second conductive wire is soldered to the third interface J6 and the other end thereof is soldered to the third pin P8.

In some embodiments, the second gold finger G5 is connected to the second pin P5 by bonding, and the third gold finger G8 is connected to the third pin P8 by bonding.

The first pad S1 is electrically connected to the first gold finger G3 through a trace 68 within the circuit board 60. In some embodiments, the trace 68 is disposed within the circuit board 60. In some embodiments, the trace 68 is disposed on the surface of the circuit board 60. For example, a discrete conductive wire is provided with one end being soldered to the first pad S1 and the other end thereof being soldered to the first gold finger G3. The conductive wire serves as the trace 68.

Similarly, the second pad S2 is electrically connected to the second gold finger G5 through a trace 68 within the circuit board 60. In some embodiments, the trace 68 is disposed within the circuit board 60. In some embodiments, the trace 68 is disposed on the surface of the circuit board 60. For example, a discrete conductive wire is provided with one end being soldered to the second pad S2, and the other end thereof being soldered to the second gold finger G5. The conductive wire serves as the trace 68.

The third pad S3 is electrically connected to the third gold finger G8 through a trace 68 within the circuit board 60. In some embodiments, the trace 68 is disposed within the circuit board 60. In some embodiments, the trace 68 is disposed on the surface of the circuit board 60. For example, a discrete conductive wire is provided with one end being soldered to the third pad S3 and the other end thereof being soldered to the third gold finger G8. The conductive wire serves as the trace 68.

To facilitate connection, the second pad S2 and the third pad S3 are disposed adjacent to the first pad S1. For example, the second pad S2 and the third pad S3 are disposed on different sides of the first pad S1. In some embodiments, the second pad S2 is disposed on the right side of the first pad S1, and the third pad S3 is disposed on the lower side of the first pad S1.

The multiple pads disposed on the circuit board 60 further include a fourth pad S4. In some embodiments, the fourth pad S4 is a grounded pad for providing a grounding path for the circuit board 60 or an element mounted on the circuit board 60. For example, in a case where a capacitor element is mounted on the circuit board 60, one electrode plate of the capacitor is directly soldered to the fourth pad S4.

The first pad S1 and the second pad S2 are connected through a conductor 72 disposed on the surface of the circuit board 60. The first pad S1 and the third pad S3 are connected through a conductor 74 disposed on the surface of the circuit board 60. Both the conductor 72 and the conductor 74 are excellent conductive bodies with low resistance values, which may be considered to be almost zero. The conductor 72 and the conductor 74 may be made of copper, aluminum, silver, or other materials. Structures and fabrication methods of the conductor 72 and the conductor 74 may refer to those of a conductor 51 in FIG. 18.

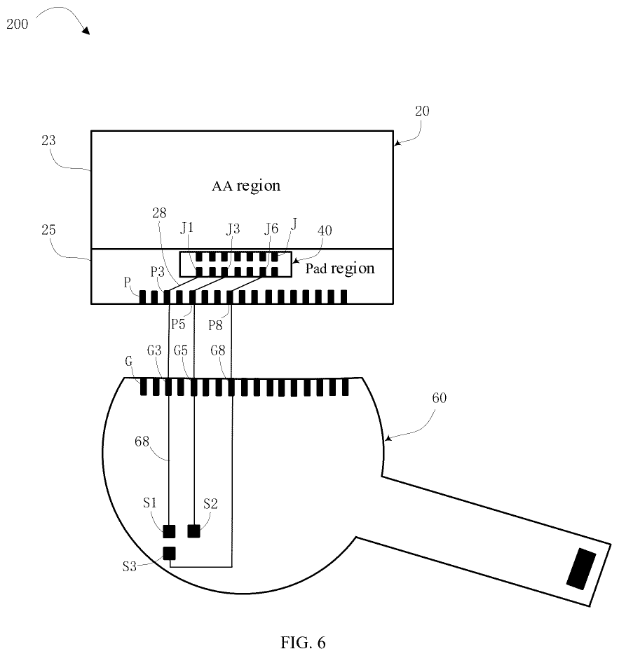

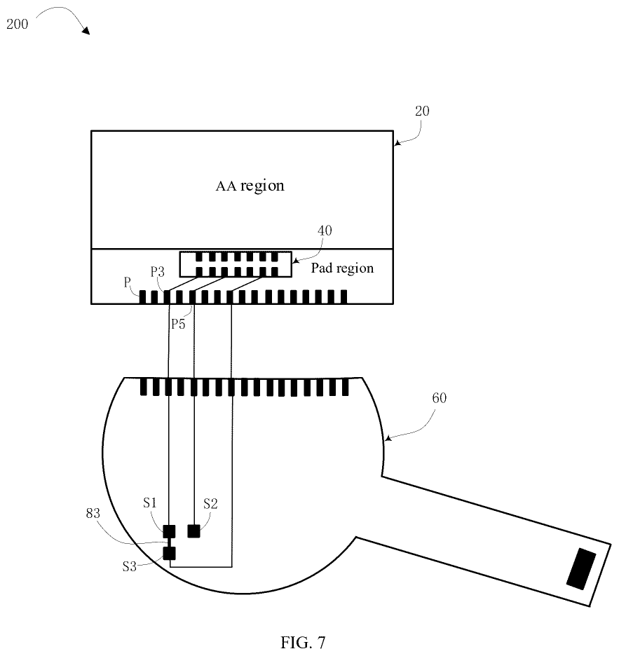

FIG. 6 is a structural schematic diagram of another display panel 200 according to some embodiments of the present disclosure. FIG. 7 is a schematic diagram of an operating state of the display panel 200 shown in FIG. 6. FIG. 8 is a schematic diagram of another operating state of the display panel 100 shown in FIG. 6.

Referring to FIG. 6, the display panel 200 includes a display substrate 20, a driving chip 40, and a circuit board 60. The display substrate 20 includes a display region 23 (AA region) and a bonding region 25 (pad region), and the bonding region 25 is provided with multiple pins P, and the multiple pins P include a first pin P3.

The driving chip 40 is disposed in the bonding region 25 of the display substrate 20 and includes multiple interfaces J, the multiple interfaces J include an enable interface J1 (i.e., an EN interface or an EN PIN), the enable interface J1 is configured to control the use of a specific communication protocol, and the enable interface J1 is electrically connected to the first pin P3.

The circuit board 60 includes multiple gold fingers G, the multiple gold fingers G include a first gold finger G3, and the multiple gold fingers G of the circuit board 60 are connected to the multiple pins P, and the first gold finger G3 is connected to the first pin P3.

Through the circuit board 60, a first potential signal or a second potential signal is applicable to the enable interface J1. In response to the first potential signal being applied to the enable interface J1, the specific communication protocol is not used; and in response to the second potential signal being applied to the enable interface, the specific communication protocol is used.

In the above embodiments, the specific communication protocol is either selected for use or not. This is conducive to exerting the advantages of the communication protocol and avoiding its disadvantages. For example, when it is detected that the moment is suitable for using the communication protocol, the second potential signal is applied to the enable interface, so that the specific communication protocol is used. When it is detected that the moment is not suitable for using the communication protocol, the first potential signal is applied to the enable interface, so that the specific communication protocol is not used.

There are various positional relationships between the display region 23 and the bonding region 25. In some embodiments, the display region 23 is a main portion of the display substrate 20, which includes multiple pixel units for displaying images; and the bonding region 25 is disposed on one edge of the display substrate 20 to enable electrical connection to external components. In some embodiments, the display region 23 is adjacent to the bonding region 25.

There are various arrangement modes for the multiple pins P. In some embodiments, the multiple pins P are disposed on a side of the bonding region 25 distal from the display region 23 and arranged along a straight line. In other embodiments, the multiple pins P are arranged along multiple sides of the bonding region 25. For example, the multiple pins P are arranged along three outer sides of the bonding region 25 (excluding a side of the bonding region 25 adjacent to the display region 23).

There are various mounting methods for the driving chip 40. In some embodiments, the driving chip 40 is mounted in the bonding region 25 in a bonding manner. In some embodiments, the driving chip 40 is mounted in the bonding region 25 by plug-in connection. For example, the driving chip 40 is provided with a connector, and the bonding region 25 is provided with a matching connector. By plugging the connector into the matching connector, the driving chip 40 is mounted in the bonding region 25.

The enable interface J1 is electrically connected to the first pin P3 through a trace 28 in the bonding region 25. In some embodiments, the trace 28 is disposed inside the bonding region 25 of the display substrate 20. In some embodiments, the trace 28 is disposed on a surface of the bonding region 25 of the display substrate 20. For example, after the driving chip 40 is mounted in the bonding region 25, a discrete conductive wire is provided with one end being soldered to the enable interface J1 and the other end being soldered to the first pin P3. The conductive wire serves as the trace 28.

The communication protocol may be any communication protocol. In some embodiments, the communication protocol is the QSPI protocol. The QSPI protocol, i.e., the queue serial peripheral interface communication protocol, is set such that in a case where the display panel is in the AOD mode, the QSPI protocol is used. Because in the AOD mode, the display panel does not need to transmit high-speed signals and handles very little data, and the use of the QSPI communication protocol is optimal, which helps reduce the workload of the driving chip. It may further be set such that in a case where the display panel is in other modes (for example, a normal display mode), the QSPI protocol is not used, and other protocols are used. The other protocols include the MIPI protocol. The MIPI protocol transmits high-speed signals with a large data volume, low power consumption, and excellent anti-interference performance.

In some embodiments, the multiple gold fingers G of the circuit board 60 are connected to the multiple pins P by bonding, and the first gold finger G3 is connected to the first pin P3 by bonding.

The multiple gold fingers G are arranged in various ways. In some embodiments, the multiple gold fingers G are disposed on a side of the circuit board 60 adjacent to the bonding region 25 and arranged along a straight line.

In some embodiments, the circuit board 60 is a flexible printed circuit (FPC) board.

In some embodiments, the first potential signal is a high-potential signal, and the second potential signal is a low-potential signal. That is, in response to the high-potential signal being applied to the enable interface J1, the specific communication protocol is not used; and in response to the low-potential signal being applied to the enable interface J1, the specific communication protocol is used.

Further, the multiple interfaces J further include a second interface J3 and a third interface J6. The second interface J3 is configured to provide a second potential signal, and the third interface J6 is configured to provide a first potential signal. The multiple pins P further include a second pin P5 and a third pin P8. The second interface J3 is electrically connected to the second pin P5, and the third interface J6 is electrically connected to the third pin P8.

The multiple gold fingers G further include a second gold finger G5 and a third gold finger G8, the second gold finger G5 is connected to the second pin P5, and the third gold finger G8 is connected to the third pin P8.

The circuit board 60 further includes multiple pads, the multiple pads include a first pad S1, a second pad S2 and a third pad S3, the first pad S1 is electrically connected to the first gold finger G3, the second pad S2 is electrically connected to the second gold finger G5, and the third pad S3 is electrically connected to the third gold finger G8.

Due to the above connection, the first pad S1 is electrically connected to the enable interface J1; the second pad S2 is electrically connected to the second interface J3 and has a second potential; and the third pad S3 is electrically connected to the third interface J6 and has a first potential.

In a case where the specific communication protocol is not required, the first pad S1 and the third pad S3 are connected, as shown in FIG. 7, such that the enable interface J1 is connected to the first potential signal; and at this time, the second interface J3 and the second pad S2 that have the second potential are in a floating state.

In a case where the specific communication protocol is required, the first pad S1 is connected to the second pad S2 may be connected, as shown in FIG. 8, such that the enable interface J1 is connected to the second potential signal; and at this time, the third interface J6 and the third pad S3 that have the first potential are in a floating state.

Referring to FIGS. 6 to 8, the second interface J3 is electrically connected to the second pin P5 through a trace 28 in the bonding region 25; and the third interface J6 is electrically connected to the third pin P8 through a trace 28 in the bonding region 25. In some embodiments, the trace 28 for connecting the second interface J3 and the second pin P5 and/or the trace 28 for connecting the third interface J6 and the third pin P8 are/is disposed inside the bonding region 25 of the display substrate 20. In some embodiments, the trace 28 for connecting the second interface J3 and the second pin P5 and/or the trace 28 for connecting the third interface J6 and the third pin P8 are disposed on a surface of the bonding region 25 of the display substrate 20. For example, after the driving chip 40 is mounted in the bonding region 25, two discrete conductive wires are provided, wherein one end of a first conductive wire is soldered to the second interface J3 and the other end thereof is soldered to the second pin P5; and one end of a second conductive wire is soldered to the third interface J6 and the other end thereof is soldered to the third pin P8.

In some embodiments, the second gold finger G5 is connected to the second pin P5 by bonding, and the third gold finger G8 is connected to the third pin P8 by bonding.

The first pad S1 is electrically connected to the first gold finger G3 through a trace 68 within the circuit board 60. In some embodiments, the trace 68 is disposed within the circuit board 60. In some embodiments, the trace 68 is disposed on the surface of the circuit board 60. For example, a discrete conductive wire is provided with one end being soldered to the first pad S1 and the other end thereof being soldered to the first gold finger G3. The conductive wire serves as the trace 68.

Similarly, the second pad S2 is electrically connected to the second gold finger G5 through a trace 68 within the circuit board 60. In some embodiments, the trace 68 is disposed within the circuit board 60. In some embodiments, the trace 68 is disposed on the surface of the circuit board 60. For example, a discrete conductive wire is provided with one end being soldered to the second pad S2 and the other end thereof being soldered to the second gold finger G5. The conductive wire serves as the trace 68.

The third pad S3 is electrically connected to the third gold finger G8 through a trace 68 within the circuit board 60. In some embodiments, the trace 68 is disposed within the circuit board 60. In some embodiments, the trace 68 is disposed on the surface of the circuit board 60. For example, a discrete conductive wire is provided with one end being soldered to the third pad S3 and the other end being soldered to the third gold finger G8. The conductive serves as the trace 68.

To facilitate connection, the second pad S2 and the third pad S3 are disposed adjacent to the first pad S1. For example, the second pad S2 and the third pad S3 are disposed on different sides of the first pad S1. In some embodiments, the second pad S2 is disposed on the right side of the first pad S1, and the third pad S3 is disposed on the lower side of the first pad S1.

These embodiments differ from those shown in FIGS. 3 to 5 in that the multiple pads disposed on the circuit board 60 include no fourth pads for grounding.

The first pad S1 and the second pad S2 are connected through a conductor 85 disposed on the surface of the circuit board 60. The first pad S1 and the third pad S3 are connected through a conductor 83 disposed on the surface of the circuit board 60. Both the conductor 85 and the conductor 83 are excellent conductive bodies with low resistance values, which may be considered to be almost zero. The conductor 85 and the conductor 83 may be made of copper, aluminum, silver, or other materials. Structures and fabrication methods of the conductor 85 and the conductor 83 may refer to those of a conductor 51 in FIG. 18.

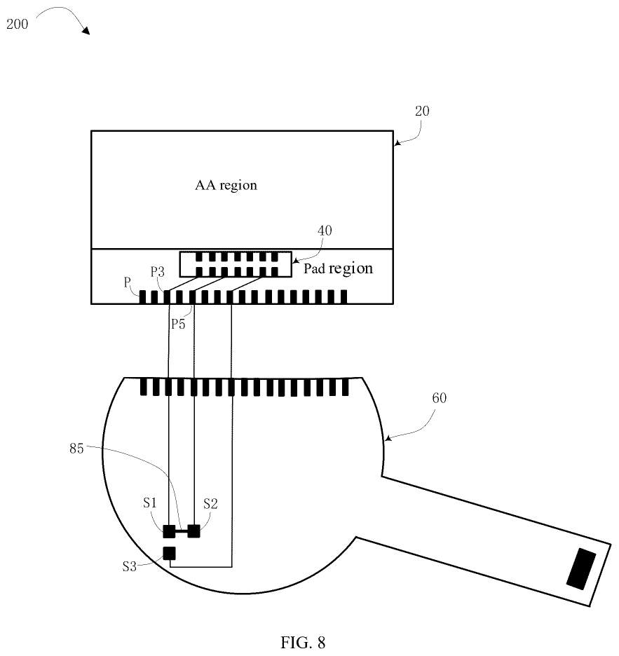

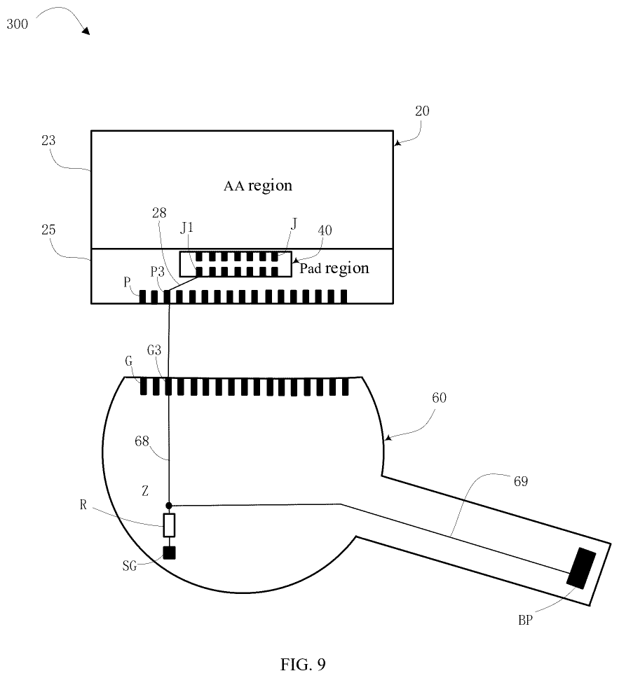

FIG. 9 is a structural schematic diagram of yet another display panel according to some embodiments of the present disclosure.

Referring to FIG. 9, the display panel 300 includes a display substrate 20, a driving chip 40, and a circuit board 60. The display substrate 20 includes a display region 23 (AA region) and a bonding region 25 (pad region), the bonding region 25 is provided with multiple pins P, and the multiple pins P include a first pin P3.

The driving chip 40 is disposed in the bonding region 25 of the display substrate 20 and includes multiple interfaces J. The multiple interfaces J include an enable interface J1 (i.e., an EN interface or an EN PIN). The enable interface J1 is configured to control the use of a specific communication protocol, and the enable interface J1 is electrically connected to the first pin P3.

The circuit board 60 includes multiple gold fingers G, the multiple gold fingers G include a first gold finger G3, the multiple gold fingers G of the circuit board 60 are connected to the multiple pins P, and the first gold finger G3 is connected to the first pin P3.

Through the circuit board 60, a first potential signal or a second potential signal is applicable to the enable interface J1. In response to the first potential signal being applied to the enable interface J1, the specific communication protocol is not used; and in response to the second potential signal being applied to the enable interface, the specific communication protocol is used.

In the above embodiments, the specific communication protocol is either selected for use or not. This is conducive to exerting the advantages of the communication protocol and avoiding its disadvantages. For example, when it is detected that the moment is suitable for using the communication protocol, the second potential signal is applied to the enable interface, so that the specific communication protocol is used. When it is detected that the moment is not suitable for using the communication protocol, the first potential signal is applied to the enable interface, so that the specific communication protocol is not used.

There are various positional relationships between the display region 23 and the bonding region 25. In some embodiments, the display region 23 is a main portion of the display substrate 20, which includes multiple pixel units for displaying images; and the bonding region 25 is disposed on one edge of the display substrate 20 to enable electrical connection to external components. In some embodiments, the display region 23 is adjacent to the bonding region 25.

There are various arrangement modes for the multiple pins P. In some embodiments, the multiple pins P are disposed on a side of the bonding region 25 distal from the display region 23 and arranged along a straight line. In other embodiments, the multiple pins P are arranged along multiple sides of the bonding region 25. For example, the multiple pins P are arranged along three outer sides of the bonding region 25 (excluding a side of the bonding region 25 adjacent to the display region 23).

There are various mounting methods for the driving chip 40. In some embodiments, the driving chip 40 is mounted in the bonding region 25 in a bonding manner. In some embodiments, the driving chip 40 is mounted in the bonding region 25 by plug-in connection. For example, the driving chip 40 is provided with a connector, and the bonding region 25 is provided with a matching connector. By plugging the connector into the matching connector, the driving chip 40 is mounted in the bonding region 25.

The enable interface J1 is electrically connected to the first pin P3 through a trace 28 in the bonding region 25. In some embodiments, the trace 28 is disposed inside the bonding region 25 of the display substrate 20. In some embodiments, the trace 28 is disposed on a surface of the bonding region 25 of the display substrate 20. For example, after the driving chip 40 is mounted in the bonding region 25, a discrete conductive wire is provided with one end being soldered to the enable interface J1 and the other end being soldered to the first pin P3. The conductive wire serves as the trace 28.

The communication protocol may be any communication protocol. In some embodiments, the communication protocol is the QSPI protocol. The QSPI protocol, i.e., the queue serial peripheral interface communication protocol, is set such that in a case where the display panel is in the AOD mode, the QSPI protocol is used. Because in the AOD mode, the display panel does not need to transmit high-speed signals and handles very little data, and the use of the QSPI communication protocol is optional, which helps reduce the workload of the driving chip. It may further be set such that in a case where the display panel is in other modes (for example, a normal display mode), the QSPI protocol is not used, and other protocols are used. The other protocols include the MIPI protocol. The MIPI protocol transmits high-speed signals with a large data volume, low power consumption, and excellent anti-interference performance.

In some embodiments, the multiple gold fingers G of the circuit board 60 are connected to the multiple pins P by bonding, and the first gold finger G3 is connected to the first pin P3 by bonding.

The multiple gold fingers G are arranged in various ways. In some embodiments, the multiple gold fingers G are disposed on a side of the circuit board 60 adjacent to the bonding region 25 and arranged along a straight line.

In some embodiments, the circuit board 60 is a flexible printed circuit (FPC) board.

In some embodiments, the first potential signal is a high-potential signal, and the second potential signal is a low-potential signal. That is, in response to the high-potential signal being applied to the enable interface J1, the specific communication protocol is not used; and in response to the low-potential signal being applied to the enable interface J1, the specific communication protocol is used.

Further, the circuit board 60 further includes a fifth pad SG and a board-to-board interface BP (i.e., B2B PIN). The fifth pad SG has a first potential (i.e., a high potential) and is configured to provide a first potential signal to the first gold finger G3. In some embodiments, the fifth pad SG is a grounded pad connected to ground. A resistor element R is connected between the fifth pad SG and the first gold finger G3.

In response to the circuit board 60 being connected to another circuit board, the board-to-board interface BP is electrically connected to or in direct contact with a corresponding interface on another circuit board. Another circuit board is connected to a controller of the electronic device to which the display panel 300 belongs, and provides a signal to the board-to-board interface BP. The board-to-board interface BP has two states: a first state in which it maintains a high-impedance (Hi-Z) state or a floating state; and a second state in which it receives a second potential signal and has a second potential (i.e., a low potential). The board-to-board interface BP is electrically connected to the first gold finger G3. In some embodiments, in addition to the board-to-board interface BP, another board-to-board interface is included, which is also configured to be electrically connected to or in direct contact with the corresponding interface on another circuit board.

No resistor element is disposed between the board-to-board interface BP and the first gold finger G3. The board-to-board interface BP and the fifth pad SG may share a segment of a trace. In some embodiments, a first end of the resistor element R is connected to the fifth pad SG, and a second end of the resistor element R is connected to the first gold finger G3 through a trace 68. The board-to-board interface BP is connected to the second end of the resistor element R or the trace 68 through a trace 69. The trace 68 or a portion thereof is shared by the board-to-board interface BP and the fifth pad SG.

The resistor element R has a relatively large resistance value. The resistance value of the resistor element R is significantly greater than the resistance values of the traces 68 and 69. In some embodiments, the resistance value of the resistor element R is 0.1 MΩ to 1 MΩ, and may, for example, be 0.1 MΩ, 0.2 MΩ, 0.3 MΩ, 0.5 MΩ, 0.7 MΩ, 0.9 MΩ, or 1 MΩ.

In a case where the specific communication protocol is not required, the board-to-board interface BP may maintain a high-impedance (Hi-Z) state or a floating state, and at this time, the enable interface J1 is provided with a first potential signal by the fifth pad SG.

In a case where the specific communication protocol is required, the board-to-board interface BP may maintain a second potential (low potential), and at this time, the fifth pad SG is equivalent to being short-circuited, and the enable interface J1 is provided with a second potential signal by the board-to-board interface BP.

In some embodiments, the trace 68 is disposed within the circuit board 60. In some embodiments, the trace 68 is disposed on the surface of the circuit board 60. For example, a discrete conductive wire is provided with one end being soldered to the second end of the resistor element R, and the other end being soldered to the first gold finger G3. The conductive wire serves as the trace 68.

In some embodiments, the trace 69 is disposed within the circuit board 60. In some embodiments, the trace 69 is disposed on the surface of the circuit board 60. For example, a discrete conductive wire is provided with one end being soldered to the second end of the resistor element R and the other end being soldered to the board-to-board interface BP. The conductive wire serves as the trace 69.

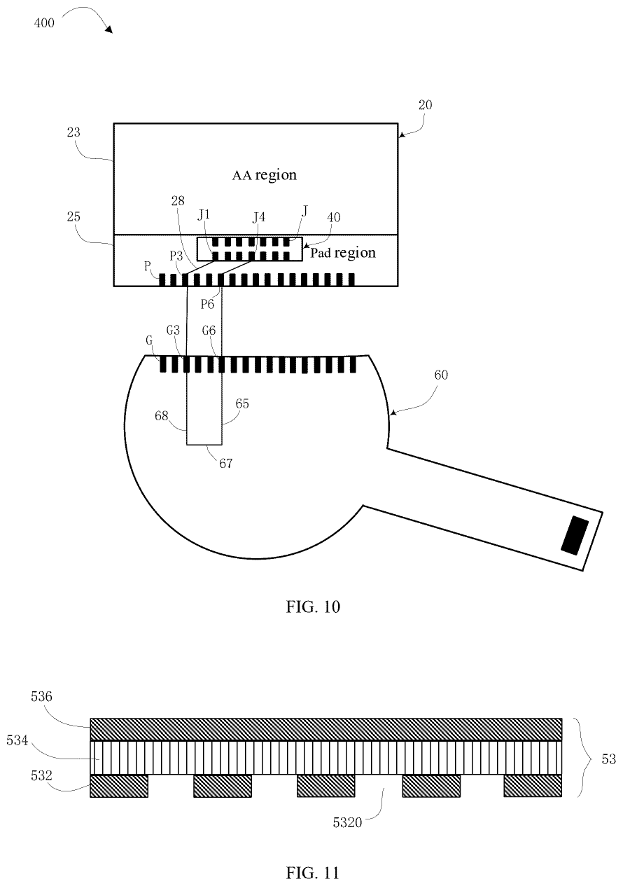

FIG. 10 is a structural schematic diagram of still yet another display panel 400 according to some embodiments of the present disclosure.

Referring to FIG. 10, the display panel 400 includes a display substrate 20, a driving chip 40, and a circuit board 60. The display substrate 20 includes a display region 23 (AA region) and a bonding region 25 (pad region), and the bonding region 25 is provided with multiple pins P, and the multiple pins P include a first pin P3.

The driving chip 40 is disposed in the bonding region 25 of the display substrate 20 and includes multiple interfaces J. The multiple interfaces J include an enable interface J1 (i.e., an EN interface or an EN PIN). The enable interface J1 is configured to control the use of a specific communication protocol, and the enable interface J1 is electrically connected to the first pin P3.

The circuit board 60 includes multiple gold fingers G, the multiple gold fingers G include a first gold finger G3, the multiple gold fingers G of the circuit board 60 are connected to the multiple pins P, and the first gold finger G3 is connected to the first pin P3.

Through the circuit board 60, a first potential signal or a second potential signal is applicable to the enable interface J1. In response to the first potential signal being applied to the enable interface J1, the specific communication protocol is not used; and in response to the second potential signal being applied to the enable interface, the specific communication protocol is used.

In the above embodiments, the specific communication protocol is either selected for use or not. This is conducive to exerting the advantages of the communication protocol and avoiding its disadvantages. For example, when it is detected that the moment is suitable for using the communication protocol, the second potential signal is applied to the enable interface, so that the specific communication protocol is used. When it is detected that the moment is not suitable for using the communication protocol, the first potential signal is applied to the enable interface, so that the specific communication protocol is not used.

There are various positional relationships between the display region 23 and the bonding region 25. In some embodiments, the display region 23 is a main portion of the display substrate 20, which includes multiple pixel units for displaying images; and the bonding region 25 is disposed on one edge of the display substrate 20 to enable electrical connection to external components. In some embodiments, the display region 23 is adjacent to the bonding region 25.

There are various arrangement modes for the multiple pins P. In some embodiments, the multiple pins P are disposed on a side of the bonding region 25 distal from the display region 23 and arranged along a straight line. In other embodiments, the multiple pins P are arranged along multiple sides of the bonding region 25. For example, the multiple pins P are arranged along three outer sides of the bonding region 25 (excluding a side of the bonding region 25 adjacent to the display region 23).

There are various mounting methods for the driving chip 40. In some embodiments, the driving chip 40 is mounted in the bonding region 25 in a bonding manner. In some embodiments, the driving chip 40 is mounted in the bonding region 25 by plug-in connection. For example, the driving chip 40 is provided with a connector, and the bonding region 25 is provided with a matching connector. By plugging the connector into the matching connector, the driving chip 40 is mounted in the bonding region 25.

The enable interface J1 is electrically connected to the first pin P3 through a trace 28 in the bonding region 25. In some embodiments, the trace 28 is disposed inside the bonding region 25 of the display substrate 20. In some embodiments, the trace 28 is disposed on a surface of the bonding region 25 of the display substrate 20. For example, after the driving chip 40 is mounted in the bonding region 25, a discrete conductive wire is provided with one end being soldered to the enable interface J1 and the other end being soldered to the first pin P3. The conductive wire serves as the trace 28.

The communication protocol may be any communication protocol. In some embodiments, the communication protocol is the QSPI protocol. The QSPI protocol, i.e., the queue serial peripheral interface communication protocol, is set such that in a case where the display panel is in the AOD mode, the QSPI protocol is used. Because in the AOD mode, the display panel does not need to transmit high-speed signals and handles very little data, and the use of the QSPI communication protocol is optimal, which helps reduce the workload of the driving chip. It may further be set such that in a case where the display panel is in other modes (for example, a normal display mode), the QSPI protocol is not used, and other protocols are used. The other protocols include the MIPI protocol. The MIPI protocol transmits high-speed signals with a large data volume, low power consumption, and excellent anti-interference performance.

In some embodiments, the multiple gold fingers G of the circuit board 60 are connected to the multiple pins P by bonding, and the first gold finger G3 is connected to the first pin P3 by bonding.

The multiple gold fingers G are arranged in various ways. In some embodiments, the multiple gold fingers G are disposed on a side of the circuit board 60 adjacent to the bonding region 25 and arranged along a straight line.

In some embodiments, the circuit board 60 is a flexible printed circuit (FPC) board.

In some embodiments, the first potential signal is a high-potential signal, and the second potential signal is a low-potential signal. That is, in response to the high-potential signal being applied to the enable interface J1, the specific communication protocol is not used; and in response to the low-potential signal being applied to the enable interface J1, the specific communication protocol is used.

Further, the multiple interfaces J further include a second interface J4. The second interface J4 is configured to selectively provide a first potential signal (a high-potential signal) or a second potential signal (a low-potential signal). In some embodiments, the second interface J4 is a general-purpose input/output (GPIO) interface. The second interface J4 is programmed to output the first potential signal and the second potential signal.

The multiple pins P also include a second pin P6. The second interface J4 is electrically connected to the second pin P6.

The multiple gold fingers G also include a second gold finger G6, the second gold finger G6 is connected to the second pin P6. In the circuit board 60, the second gold finger G6 is electrically connected to the first gold finger G3. In some embodiments, the second gold finger G6 is connected to the first gold finger G3 through traces 68, 67, and 65.

Due to the above connection, the enable interface J1 and the second interface J4 are electrically connected and have the same potential.

In a case where the specific communication protocol is not required, the second interface J4 is controlled to be at a first potential to provide a first potential signal to the enable interface J1.

In a case where the specific communication protocol is required, the second interface J4 is controlled to be at a second potential to provide a second potential signal to the enable interface J1.

The second interface J4 is electrically connected to the second pin P6 through a trace 28 in the bonding region 25. In some embodiments, the trace 28 for connecting the second interface J4 and the second pin P6 is disposed within the bonding region 25 of the display substrate 20. In some embodiments, the trace 28 for connecting the second interface J4 and the second pin P6 is disposed on the surface of the bonding region 25 of the display substrate 20. For example, after the driving chip 40 is mounted in the bonding region 25, a discrete conductive wire is provided with one end being soldered to the second interface J4 and the other end being soldered to the second pin P6.

In some embodiments, the second gold finger G6 is connected to the second pin P6 by bonding.

In some embodiments, the traces 68, 67, 65 are disposed inside the circuit board 60. In some embodiments, the traces 68, 67, and 65 are disposed on the surface of the circuit board 60.

The display panel in each of the above embodiments is a flexible display panel using OLED display technology.

The present disclosure further provides an electronic device. The electronic device includes the various display panels described above. In some embodiments, the electronic device is a wearable device. The wearable device may be a watch.

The present disclosure further provides a method for manufacturing a display panel. The method is used to manufacture the various display panels described above. The method for manufacturing the display panel includes the following steps.
providing a display substrate, a driving chip, and a circuit board, wherein
the display substrate includes a display region and a bonding region, the display region includes multiple pixel units, the bonding region is provided with multiple pins, and the multiple pins include a first pin;
mounting the driving chip in the bonding region of the display substrate, wherein the driving chip includes multiple interfaces, the multiple interfaces include an enable interface, the enable interface is configured to control the use of a communication protocol, and the enable interface is electrically connected to the first pin; and
connecting the circuit board to the display substrate, wherein the circuit board includes multiple gold fingers, the multiple gold fingers include a first gold finger, the multiple gold fingers of the circuit board are connected to the multiple pins, and the first gold finger is connected to the first pin;
through the circuit board, a first potential signal or a second potential signal is applicable to the enable interface J1; in response to the first potential signal being applied to the enable interface J1, the specific communication protocol is not used; and in response to the second potential signal being applied to the enable interface, the specific communication protocol is used.

Further, the step of providing or manufacturing a circuit board includes the following steps.

As shown in FIG. 11, a double-layer board 53 is first provided, wherein the double-layer board 53 includes a first metal layer 536, a first insulating layer 534, and a second metal layer 532. The first metal layer 536 and the second metal layer 532 are made of copper. The first insulating layer 534 is made of a flexible polyimide (PI) material to impart flexibility to the double-layer board 53. The second metal layer 532 is etched using a chemical solution to form the desired circuit pattern. The etched-away portions of the second metal layer 532 will form holes 5320.

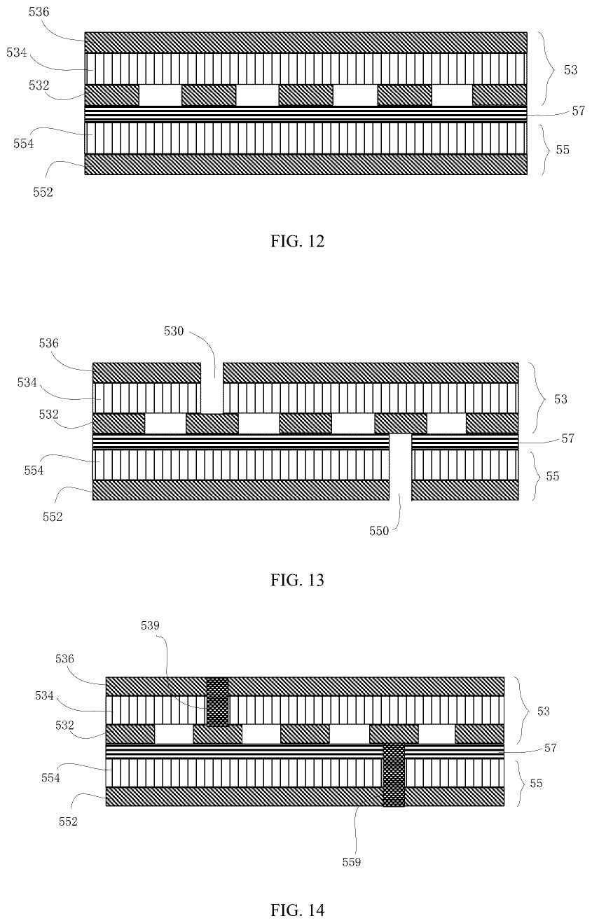

As shown in FIG. 12, a double-layer board 53 and a single-layer board 55 are adhered together using an adhesive layer 57. The adhesive layer 57 is made of AD adhesive. The single-layer board 55 includes a second insulating layer 554 and a third metal layer 552. The second insulating layer 554 is made of a flexible polyimide (PI) material to impart flexibility to the single-layer board 55. The third metal layer 552 is made of copper.

As shown in FIG. 13, by using a laser drilling process, a contact hole 530 is formed in the double-layer board 53, and a contact hole 550 is formed in the single-layer board 55.

As shown in FIG. 14, the contact hole 530 is filled with a metal material to form a metal post 539, and the contact hole 550 is filled with a metal material to form a metal post 559. The metal post 539 and the metal post 559 are formed using an electroplating process. The metal post 539 and the metal post 559 are made of copper.

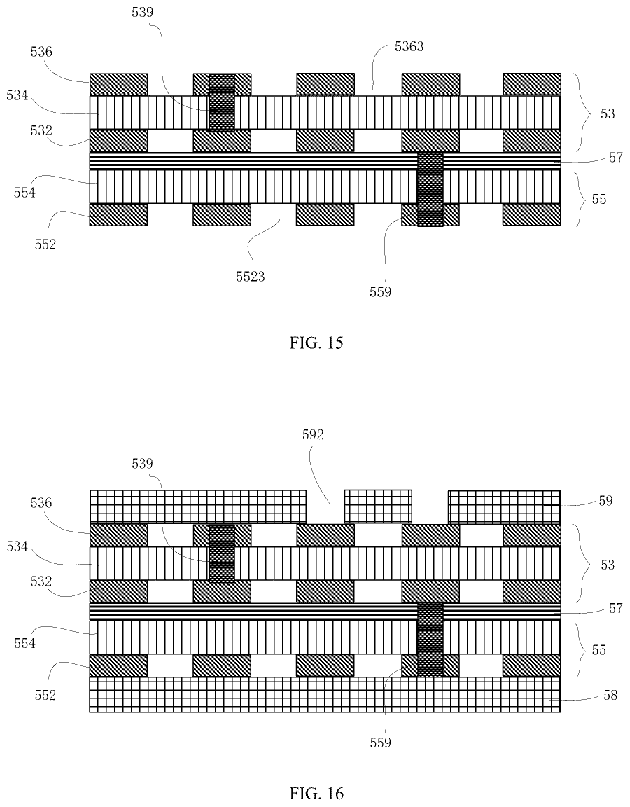

As shown in FIG. 15, the first metal layer 536 and the third metal layer 552 are etched using a chemical solution to form desired circuit patterns. Etched-away portions of the first metal layer 536 form holes 5363. Etched-away portions of the second metal layer 552 form holes 5523.

As shown in FIG. 16, the first metal layer 536 is covered with a first protective layer 59, and the third metal layer 552 is covered with a second protective layer 58. Holes 592 are then formed in the first protective layer 59. The metal structures exposed by these holes 592 serve as pads. These pads are the first pad, the second pad, and the third pad described above.

A conventional three-layer circuit board (flexible printed circuit board) is relatively thick, compressing the internal space of the display panel and the entire electronic device. The embodiment of the present disclosure utilizes a structure including a double-layer board and a single-layer board, which can significantly reduce the overall thickness of the circuit board. The double-layer board is configured for routing of signal lines, while the single-layer board is mostly covered with solid metal to shield signal interference.

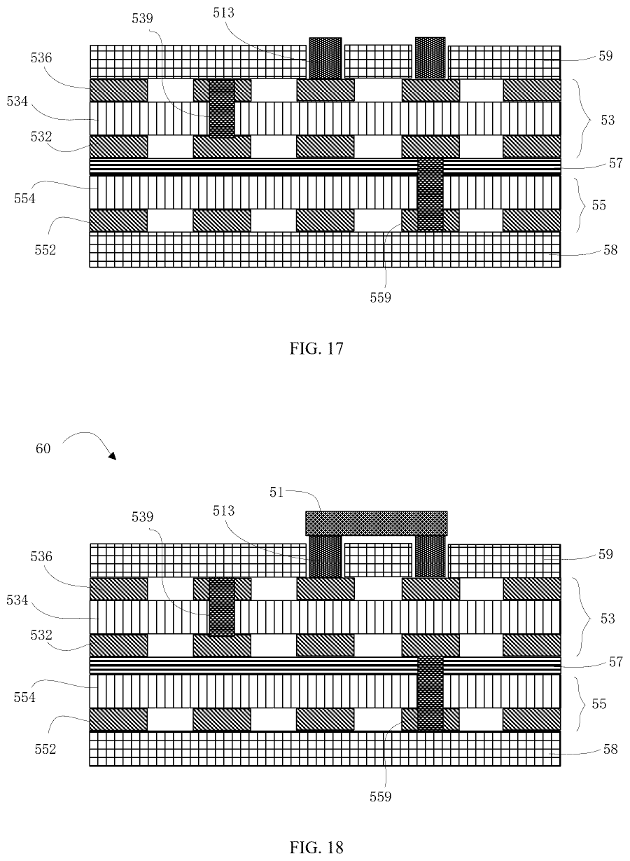

As shown in FIG. 17, solder paste 513 is formed in the hole 592. The solder paste 513 is made of tin. The solder paste 513 is electrically connected to the pad below the hole 592.

As shown in FIG. 18, a conductor 51 is formed above the first protective layer 59 and the solder paste 513. The conductor 51 is made of a metal material, such as copper. After the conductor 51 is placed on the solder paste 513, the connection and fixing between the conductor 51 and the solder paste 513 may be cured through an annealing process. The conductor 51 is configured to connect two different pads.

In the present disclosure, the different embodiments may be complementary without conflict.

In the present disclosure, the terms “first” and “second” are for descriptive purposes only and are not to be understood as indicating or implying relative importance. The terms “a plurality of/multiple”, “several” mean two or more, unless otherwise expressly defined.

Other embodiments of the present disclosure will be readily conceived by those skilled in the art upon consideration of the specification and practice of the present disclosure disclosed herein. The present disclosure is intended to cover any variations, uses, or adaptations of the present disclosure following general principles of the present disclosure and including the common general knowledge or customary technical means in the art which is not disclosed in the present disclosure. The specification and embodiments are to be considered as exemplary only, with a true scope and spirit of the present disclosure indicated by the following claims.

It should be understood that the present disclosure is not limited to the exact construction that has been described above and illustrated in the accompanying drawings, and that various modifications and changes can be made without departing from the scope thereof. The scope of the present disclosure is limited only by the appended claims.

1. A display panel, comprising:
a display substrate having a display region and a bonding region, wherein the display region comprises a plurality of pixel units and the bonding region is provided with a plurality of pins comprising a first pin;
a driving chip disposed on the bonding region, wherein the driving chip is provided with a plurality of interfaces comprising an enable interface, and the enable interface is configured to enable a communication protocol and the enable interface is connected to the first pin; and
a circuit board, wherein the circuit board is provided with a plurality of gold fingers comprising a first gold finger, the plurality of gold fingers are connected to the plurality of pins, and the first gold finger is connected to the first pin,
wherein in response to a first potential signal being applied to the enable interface through the circuit board, the communication protocol is not used; and in response to a second potential signal being applied to the enable interface through the circuit board, the communication protocol is used.

2. The display panel according to claim 1, wherein the communication protocol comprises a queue serial peripheral interface (QSPI) protocol.

3. The display panel according to claim 2, wherein a mobile industry processor interface (MIPI) communication protocol is used in response to the QSPI protocol being not used.

4. The display panel according to claim 1, wherein the plurality of gold fingers of the circuit board are connected to the plurality of pins in a bonding manner, and the first gold finger is connected to the first pin in the bonding manner.

5. The display panel according to claim 1, wherein the first potential signal is a high-potential signal, and the second potential signal is a low-potential signal.

6. The display panel according to claim 1, wherein the plurality of interfaces further comprise a second interface and a third interface, wherein one of the second interface and the third interface is configured to provide the first potential signal, and the other thereof is configured to provide the second potential signal;
the plurality of pins further comprise a second pin and a third pin, wherein the second interface is connected to the second pin, and the third interface is connected to the third pin;
the plurality of gold fingers further comprise a second gold finger and a third gold finger, wherein the second gold finger is connected to the second pin, and the third gold finger is connected to the third pin;
the circuit board further comprises a plurality of pads, wherein the plurality of pads comprise a first pad, a second pad, and a third pad, wherein the first pad is connected to the first gold finger, the second pad is connected to the second gold finger, and the third pad is connected to the third gold finger; and
the first pad is selectively connected to either the second pad or the third pad.

7. The display panel according to claim 6, wherein the second gold finger is connected to the second pin in a bonding manner, and the third gold finger is connected to the third pin in a bonding manner.

8. The display panel according to claim 6, wherein the first pad is connected to the first gold finger through a trace inside the circuit board, the second pad is connected to the second gold finger through a trace inside the circuit board, and the third pad is connected to the third gold finger through a trace inside the circuit board.

9. The display panel according to claim 6, wherein the second pad and the third pad are both adjacent to the first pad, and the second pad and the third pad are disposed on different sides of the first pad.

10. The display panel according to claim 6, wherein the first pad is connected to the second pad through a conductor disposed on a surface of the circuit board; or the first pad is connected to the third pad through a conductor disposed on a surface of the circuit board.

11. The display panel according to claim 1, wherein the circuit board further comprises a fifth pad and a board-to-board interface, wherein
the fifth pad has a first potential and provides the first potential signal to the first gold finger, and a resistor element is connected between the fifth pad and the first gold finger; and
the board-to-board interface is connected to the first gold finger and is switchable between a first state and a second state; and when the board-to-board interface is in the first state, the board-to-board interface is in a high-impedance state or a floating state, and when the board-to-board interface is in the second state, the board-to-board interface has a second potential and provides the second potential signal to the enable interface.

12. The display panel according to claim 11, wherein the fifth pad is grounded.

13. The display panel according to claim 1, wherein the plurality of interfaces further comprise a second interface configured to selectively provide the first potential signal or the second potential signal;
the plurality of pins further comprise a second pin connected to the second interface; and
the plurality of gold fingers further comprise a second gold finger connected to the second pin, the second gold finger being connected to the first gold finger.

14. The display panel according to claim 13, wherein the second interface is a general-purpose input/output (GPIO) interface; and the second interface is programmable to output the first potential signal or the second potential signal.

15. An electronic device, comprising a display panel, wherein the display panel comprises:
a display substrate having a display region and a bonding region, wherein the display region comprises a plurality of pixel units and the bonding region is provided with a plurality of pins comprising a first pin;
a driving chip disposed on the bonding region, wherein the driving chip is provided with a plurality of interfaces comprising an enable interface, wherein the enable interface is configured to enable a communication protocol and the enable interface is connected to the first pin; and
a circuit board, wherein the circuit board is provided with a plurality of gold fingers comprising a first gold finger, the plurality of gold fingers are connected to the plurality of pins, and the first gold finger is connected to the first pin,
wherein in response to a first potential signal being applied to the enable interface through the circuit board, the communication protocol is not used; and in response to a second potential signal being applied to the enable interface through the circuit board, the communication protocol is used.

16. The electronic device according to claim 15, wherein the communication protocol comprises a queue serial peripheral interface (QSPI) protocol.

17. The electronic device according to claim 16, wherein a mobile industry processor interface (MIPI) communication protocol is used in response to the QSPI protocol being not used.

18. The electronic device according to claim 15, wherein the plurality of gold fingers of the circuit board are connected to the plurality of pins in a bonding manner, and the first gold finger is connected to the first pin in the bonding manner.

19. The electronic device according to claim 15, wherein the first potential signal is a high-potential signal, and the second potential signal is a low-potential signal.

20. The electronic device according to claim 15, wherein the plurality of interfaces further comprise a second interface and a third interface, wherein one of the second interface and the third interface is configured to provide the first potential signal, and the other thereof is configured to provide the second potential signal;
the plurality of pins further comprise a second pin and a third pin, wherein the second interface is connected to the second pin, and the third interface is connected to the third pin;
the plurality of gold fingers further comprise a second gold finger and a third gold finger, wherein the second gold finger is connected to the second pin, and the third gold finger is connected to the third pin;
the circuit board further comprises a plurality of pads, wherein the plurality of pads comprise a first pad, a second pad, and a third pad, wherein the first pad is connected to the first gold finger, the second pad is connected to the second gold finger, and the third pad is connected to the third gold finger; and
the first pad is selectively connected to either the second pad or the third pad.
